(19) United States
(12) Patent Application Publication
(10) Pub. No.: US 2007/0076810 A1
(43) Pub. Date: Apr. 5, 2007

(54) System and method for selecting transmission format using effective SNR

(76) Inventors: Alfonso Rodriguez Herrera, Mexico (MX); Sean M. McBeath, Keller, TX (US); Danny T. Pinckley, Arlington, TX (US); John D. Reed, Arlington, TX (US)

Correspondence Address: INGRASSIA FISHER & LORENZ, P.C., 7150 E. CAMELBACK, STE. 325, SCOTTSDALE, AZ, 85251, US

(21) Appl. No.: 11/241,840

(22) Filed: Sep. 30, 2005

(51) Int. Cl. H04L 5/12; H03K 7/06

(52) U.S. Cl. 375/261; 375/271

(57) ABSTRACT

Methods and systems are provided for determining a transmission format using an effective SNR. The method comprises determining (105) a pilot SNR for at least one time period in a frame, mapping (110, 115, 120, and 125) the scaled SNRs of the frame to a second SNR for at least one transmission format, and selecting (130) the transmission format based on the second SNRs. The system comprises a receiver (24) configured to detect pilot signals, a data storage (36), and a processor (26) coupled to the receiver and data storage. The data storage (36) comprises tables of capacity mapping functions and Q factors for each transmission format The processor (26) comprises a set of instructions to convert SNRs of different pilot signals to a second SNR using the tables and Q factors and select the transmission format based on the second SNR.

### FIELD OF THE INVENTION

The present invention generally relates to communication systems, and more particularly relates to a system and a method for determining a transmission format at an access terminal to communicate with an access network.

### BACKGROUND OF THE INVENTION

Multiple-access modulation, such as Code Division Multiple Access (CDMA), and multi-channel modulation, such as Orthogonal Frequency Division Multiplexing (OFDM), are examples of techniques commonly used for broadband high data rate communications. In a CDMA2000 High Rate Packet Data (HRPD) system, rate control is generally used to achieve multi-user diversity. Each Access Terminal (AT) in the system reports a data rate request, which is derived from measured pilot Signal-to-Noise Ratios (SNRs), to an Access Network (AN), and the AN applies a scheduling algorithm to process the data rate requests and choose which AT or group of ATs is granted the next time slot on the forward link. In HRPD, a Data Rate Control (DRC) channel is typically used by the AT to request a forward traffic channel data rate to the AN. The AN can either serve the AT at the requested data rate, serve the AT from a set of compatible data rates, or decline service to the AT. To determine the transmission format, the AN generally requires access to all of the data rate requests, such as for each channel or time slot, associated with each of the ATs requesting a forward traffic channel. Acquiring all of these data rate requests from the ATs significantly increases the overhead of the system.

To determine the requested data rate in the HRPD system, the AT measures or determines the SNR of the pilot, adds a margin to the measured SNR, maps the value of the measured SNR adjusted by the margin to a data rate, and reports the requested data rate to the AN on the DRC channel. The margin is typically set to accommodate a minimum forward error rate. The performance of this HRPD system is affected by the accuracy of the determined pilot SNR. Conventional measurements of the pilot SNR may be inadequate due to variations of pilot SNRs over frequency or time. The margin added to the data rate may be increased to compensate for such variations, but increasing the margin may result in a selected data rate that is lower than the system conditions are capable of supporting.

Accordingly, a method for determining a transmission format at a receiver is desired. More particularly, a method for determining a transmission format is desired that more accurately determines an optimum transmission data rate. In addition, a system for communicating with an access network is desired that more accurately determines an optimum transmission data rate at a receiver. Furthermore, other desirable features and characteristics of the present invention will become apparent from the subsequent detailed description of the invention and the appended claims, taken in conjunction with the accompanying drawings and this background of the invention.

### BRIEF DESCRIPTION OF THE DRAWINGS

The present invention will hereinafter be described in conjunction with the following drawing figures, wherein like numerals denote like elements, and

FIG. 1 is a block diagram of an exemplary embodiment of a communication system in accordance with the present invention;

FIG. 2 is a block diagram of an exemplary embodiment of an access terminal in accordance with the present invention;

FIG. 3 is a graph of capacity mapping functions useful in understanding the communication system shown in FIG. 1;

FIG. 4 is a flow diagram of an exemplary embodiment of a method for determining a transmission format in accordance with the present invention; and

FIG. 5 is a flow diagram of an exemplary embodiment of a method for selecting a set of channels and a transmission format in accordance with the present invention.

### DETAILED DESCRIPTION

The following detailed description of the invention is merely exemplary in nature and is not intended to limit the invention or the application and uses of the invention. Furthermore, there is no intention to be bound by any theory presented in the preceding background of the invention or the following detailed description.

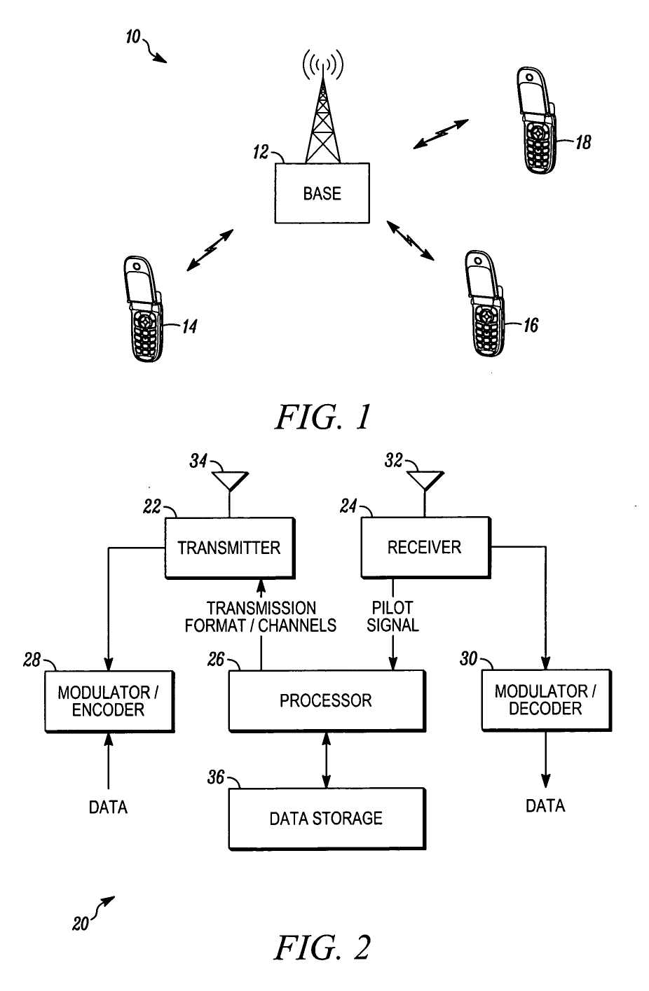

Referring to the drawings, FIG. 1 is a block diagram of an exemplary embodiment of a communication system 10 in accordance with the present invention. Communication system 10 comprises a base station or an Access Network (AN) 12 and one or more mobile stations or Access Terminals (AT) 14, 16, and 18 configured to wirelessly communicate with AN 12. A variety of communication techniques may be used to transmit information between AT 14, 16, and 18 and AN 12 including, by way of example and not limitation, spread-spectrum techniques (e.g., CDMA), multi-channel techniques such as OFDM, Evolution Data Only (EV-DO), Third Generation Partnership Project (3GPP), and the like. For simplicity of discussion, system communication between AN 12 and ATs 14, 16, and 18 is described hereinafter with respect to one AT 14, and is applicable to all ATs 14, 16, and 18 in system 10.

AT 14 measures or determines SNRs and transforms the measured or determined SNRs to produce an effective SNR that reproduces an Additive White Gaussian Noise (AWGN) performance under a wide range of channel conditions, modulation and coding schemes (MCSs), and transmission parameters (e.g., forward error rates). Typically, the measured or determined SNRs are referred to as pilot SNRs, although the measured or determined SNRs can be derived from the pilot or data. In one exemplary embodiment, AT 14 applies an Equivalent SNR method based on Convex Metric (ECM) to produce the effective SNR. In another exemplary embodiment, AT 14 applies an Exponential Effective SNR Method (EESM) to produce the effective SNR. Each modulation and coding scheme has a different effective SNR for operating within an expected Forward Error Rate (FER) and has a corresponding data rate, and AT 14 selects the transmission format based on the effective SNRs and the expected FER associated with each of the transmission formats. The expected FER may be determined from a table of SNRs required to obtain given level of performance for each transmission format, for example, a table of a one percent (1%) frame error rate SNR. The transmission format is preferably selected to optimize the data rate for one or more predetermined system constraints. Examples of such system constraints include predefined modulation and coding schemes for a particular communication technique, data error rates, packet size, throughput, delay, nominal transit duration, bandwidth, bandwidth efficiency, etc. AT 14 transmits the optimum data rate to AN 12.

The expected FERs vary for each of the transmission formats. For example, a first transmission format may have a one-hundred percent (100%) error at a corresponding effective SNR, a second transmission format may have a fifty percent (50%) error at a corresponding effective SNR, a third transmission format may have a ten percent (10%) error at a corresponding effective SNR, and a fourth transmission format may have a 0.001% error at a corresponding effective SNR. When selecting the transmission format, the acceptable expected FER may vary for a particular system constraint. For example, AT 14 may request a transmission format having high reliability, or AT 14 may request a transmission format having a higher data rate but with a one percent (1%) error, or AT 14 may request a transmission format that is capable of transmitting using one time slot rather than transmitting additional bits using four time slots. Alternatively, the expected FERs may simply be one-hundred percent (100%) or N % based on a table of SNRs required to obtain a given level of performance for each transmission format, for example, a table of an N % frame error rate SNR.

In a multiple channel embodiment of system 10, AT 14 additionally determines effective SNRs for the channels. In one exemplary embodiment, AT 14 negotiates a superset of channels in advance with AN 12 and determines an effective SNR for each of the negotiated channels in the superset. Alternatively, AT 14 calculates one effective SNR for the entire superset of channels. In another exemplary embodiment, AT 14 determines which set of superset of channels AN 12 uses by additionally determining the pilot SNRs for each available channel, determining the effective SNR for each set of the available channels and for each transmission format, determining the transmission format and set of channels which optimizes one or more of the system constraints, and reporting the determined transmission format and requested set of channels to AN 12. The set of channels is less than or equal to the superset of channels. For example, the superset may be channels {f1, f2}, and possible sets of the superset include {f1}, {f2}, and {f1, f2}. In yet another exemplary embodiment, AT 14 determines an effective SNR for each channel and for at least one transmission format, determines a transmission format that optimizes one or more of the system constraints, and reports the determined transmission format for each channel along with the corresponding channel information.

FIG. 2 is a block diagram of an exemplary embodiment of an AT 20 such as ATs 14, 16, and 18, shown in FIG. 1. AT 20 comprises a transmitter 22 having first and second inputs, a processor 26 having an output coupled to the first input of transmitter 22, a data storage 36 coupled to a second input of processor 26, a receiver 24 having a first output coupled to a second input of processor 26, a modulator/encoder 28 coupled to the second input of transmitter 22, and a demodulator/decoder 30 coupled to the second output of receiver 24. In general, receiver 24 detects pilot signals via antenna 32, demodulator/decoder 30 demodulates and decodes signals received by receiver 24 and produces a signal containing data (e.g., voice, video, text, etc.), data storage 36 stores a variety of capacity mapping functions (e.g., as look-up tables), pre-determined scale factors, and system parameters (e.g., mobile speed, general estimation error, coding amounts, and the like), processor 26 conducts transmission format selection (e.g., data rate and channel) using the pilot signals and the capacity mapping functions, transmitter 22 transmits the selected data rate and corresponding channel(s) via antenna 34, and modulator/encoder 28 modulates and encodes data (e.g., voice, video, text, etc.) into signals for transmission by transmitter 22. AT 20 may further include additional circuitry (input/output devices, signal detection circuitry and filters, etc.) associated with conventional wireless communication devices.

To select the transmission format for a single channel system, processor 26 divides the time resources into time sections and determines the SNR for each of these sections. For example, processor 26 divides a time slot into M number of time periods and determines a pilot signal SNR for each of the M time periods. In one exemplary embodiment, processor 26 determines the effective SNR for each possible transmission format using the ECM. The scaled SNR is determined by scaling the determined SNR by a factor Q that is predetermined based on the stored system parameters (e.g., mobile speed, general estimation error, modulation, coding amounts, and the like) in data storage 36. Each of the scaled SNRs is mapped to capacity by processor 26 using the capacity mapping functions stored in data storage 36 for each transmission format. Processor 26 averages the capacities of the scaled SNRs (e.g., the scaled SNRs of the M time periods in a time slot or a frame) for each transmission format, and the averaged capacity is mapped to an effective SNR using the capacity mapping functions for each transmission format.

In another exemplary embodiment, processor 26 determines the effective SNR for each possible transmission format using the EESM, and the effective SNR (SNR_{eff}) follows from

$${SNR}_{eff} = - β ln ( \frac{1}{M } {\sum }_{m = 1}^{M} {ⅇ}^{- {SNR}_{m} / β} ) ,$$

where M is the number of samples for a time-frequency unit (e.g., a frame), SNRₘ is the measured SNR associated with the m^{th} time sample, and β is a predetermined optimized constant.

The selected transmission format is then determined from the set of effective SNRs. In an exemplary embodiment, processor 26 applies a margin to the effective SNR for each possible transmission format. This margin can be different for each transmission format and may also be zero (0). Because the margin is based on maintaining a minimum forward error rate, among other system constraints, and the effective SNR more accurately reflects the SNRs of the available channels, the amount of added margin may be reduced in system 10 when compared to a system without application of the ECM or EESM. Processor 26 selects the transmission format that optimizes one or more system constraints such as data rate, reliability, or delay. For example, where one system constraint is the data rate, the SNRs are determined in one time slot and the selected transmission format is transmitted in a later time slot to AN 12. In an alternative embodiment, processor 26 does not apply margin to the effective SNR but applies a margin directly to the selected transmission format to determine a newly selected transmission format. The margin is implemented by selecting a transmission format with less stringent SNR requirements than the original selected transmission format. The frequency at which the transmission format is reported may vary such as every 1 time slot, every 2 time slots, every 4 time slots, every 8 time slots, etc.

Multi-channel systems (e.g., having N channels) may permit selection of multiple channels. For example, CDMA with a twenty (20) MHz bandwidth may have fifteen (15) channels each occupying 1.25 MHz, OFDM with a five (5) MHz bandwidth may have three-hundred thirty-six (336) channels, and OFDM with a twenty (20) MHz bandwidth may have one-thousand three-hundred forty-four (1344) channels.

In one multi-channel embodiment, AT 20 determines effective SNRs for a plurality of sets of channels from a pre-negotiated superset of channels. For example, processor 26 divides a time slot into M number of time periods and F channels, where F defines the number of channels in each set, and determines a pilot signal SNR for each of the M time periods and F channels. In an exemplary embodiment, processor 26 determines the effective SNR for each possible transmission format using the ECM as follows: 1) processor 26 determines the scaled SNR by scaling the measured SNR by a factor Q that is predetermined based on stored parameters (e.g., mobile speed, general estimation error, modulation, coding amounts, and the like) in data storage 36 for each transmission format; 2) processor 26 maps each of the scaled SNRs to capacity using the capacity mapping functions stored in data storage 36 for each transmission format; 3) processor 36 averages the capacities of the scaled SNRs (e.g., averages the scaled SNRs of the M time periods and F channels in the time slot or frame) for each transmission format; and 4) processor 26 maps the averaged capacity to an effective SNR using the capacity mapping functions for each transmission format. This process is repeated for each of the plurality of sets of channels.

In another multi-channel embodiment, processor 26 determines the effective SNR for each possible transmission format using the EESM, and the effective SNR (SNR_{eff}) follows from

$${SNR}_{eff} = - β ln ( \frac{1}{FM } {\sum }_{m = 1}^{M} {ⅇ}^{- {SNR}_{m , f} / β} ) ,$$

where M is the number of samples for a time unit (e.g., a frame), F is the number of channels, SNR_{m,f} is the measured SNR associated with the m^{th} time sample for the f^{th} channel, and β is a predetermined optimized constant. The transmission format is then determined from the set of effective SNRs and reported to AN 12.

In one exemplary embodiment, AT 20 separately determines an effective SNR for each channel, separately as in the single channel system embodiment, determines a transmission format as in the single channel system embodiment, and reports the determined transmission format to AN 12 and corresponding channel information for each channel. In another exemplary embodiment, AT 20 determines a particular set of channels from a superset of pre-negotiated channels. In this exemplary embodiment, processor 26 calculates the effective SNR for each possible transmission format using different combinations of channels. The combination of channels and transmission format meeting a set of constraints is selected by processor 26 and reported, including the corresponding channels, to AN 12. For multi-channel systems, examples of the constraints include, but are not necessarily limited to, the total number of available channels, a measure of bandwidth efficiency (bits/sec/Hz), bandwidth, throughput, delay, nominal transmit duration, expected FER, and the like. AN 12 uses the information reported from AT 20 to schedule subsequent transmissions. Typically, AN 12 serves AT 20 using the requested transmission format on the requested set of channels. Alternatively, AN 12 serves AT 20 using a compatible transmission format or a compatible set of channels. A compatible transmission format is typically one with a less stringent or equivalent SNR requirement than the reported transmission format. A compatible set of channels is typically a subset of the set of channels which were reported, where the subset of channels is less than or equal to the set of channels.

System overhead may be traded to report more than one set of channels to AN 12. The multiple sets of channels may be useful in the event of channel conflict arising from multiple ATs requesting similar channels. Additionally, the available bandwidth may be divided into resource elements to assist AT 20 in determining which channels are grouped into channel sets and for SNR reporting. For example, using fifteen (15) 1.25 MHz CDMA channels in a twenty (20) MHz bandwidth, fifteen (15) bits are used to represent every possible set of channels (e.g., 2¹⁵=32,768) of channels available for selection at AT 20. With resource elements, the AN 12 and AT 20 may predetermine that 256 sets of channels are possible (e.g., using eight (8) bits for 2⁸=256) to indicate the valid combinations of carriers and thereby decrease system overhead. In this example, the combination of carrier 1 and carrier 15 may not be a valid resource element. These sets of channels are stored at AN 12 and AT 20. In this example, using resource elements allows AT 20 to used only eight (8) bits when reporting a set of channels, thereby reducing overhead.

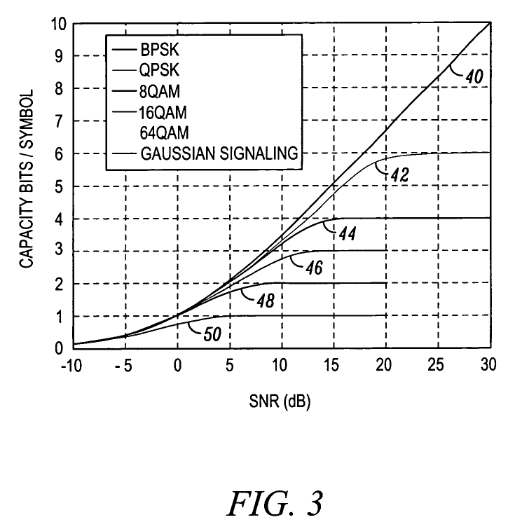

FIG. 3 is a graph of capacity mapping functions useful in understanding the communication system 10 shown in FIG. 1. AT 14 maps the measured SNRs using variety of capacity mapping functions based upon the modulation format of a particular data rate including, but not necessarily limited to, a Gaussian signaling 40, a sixty-four Quadrature Amplitude Modulation (64QAM) 42, a sixteen Quadrature Amplitude Modulation (16QAM) 44, an eight Phase Shift Keying (8PSK) 46, a Quadrature Phase Shift Keying (QPSK) 48, and a Binary Phase Shift Keying (BPSK) 50. Other modulation formats (e.g., two-hundred and fifty-six Quadrature Amplitude Modulation (256QAM)) and variations of modulation formats 40, 42, 44, 46, 48, and 50 (e.g., variations based on coding rate, preamble lengths, and packet sizes) may also be used for capacity mapping by AT 14. Most of the modulation formats have a maximum capacity, such as 1 bit/symbol for BPSK, 2 bits/symbol for QPSK, 3 bits/symbol for 8PSK, 4 bits/symbol for 16QAM, and 6 bits/symbol for 64QAM. AT 14 applies capacity mapping functions 40, 42, 44, 46, 48, and 50, to determine capacity from scaled SNRs and determine effective SNRs from frame capacities or averaged capacities.

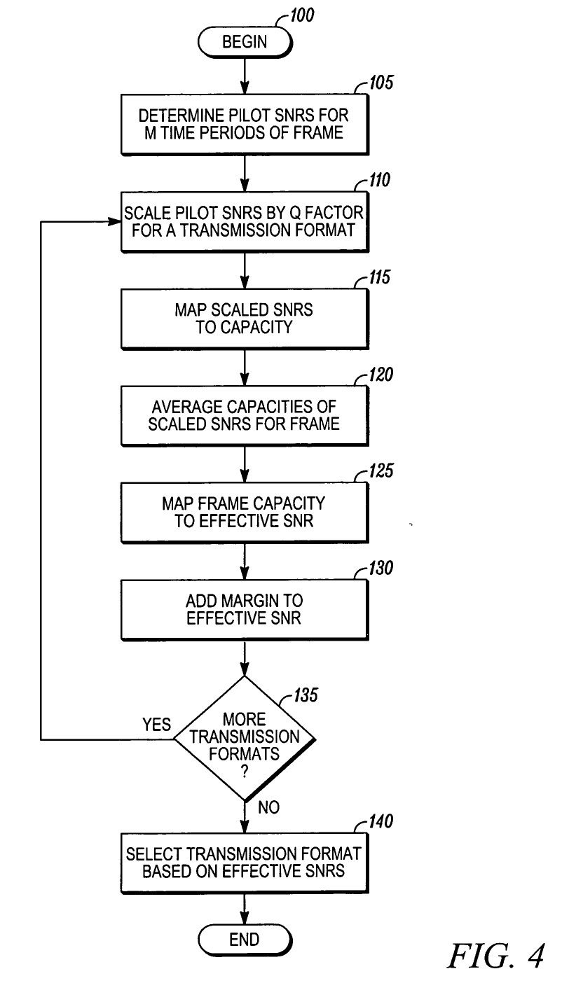

FIG. 4 is a flow diagram of an exemplary embodiment of a method 100 for mobile wireless transactions in accordance with the present invention. The SNRs for available pilot signals are measured or determined at step 105. For example, pilot SNRs for M time periods of a frame are determined. The determined SNRs are scaled by a factor Q based on a transmission format at step 110. The scaled SNRs are each mapped to capacity at step 115. The capacities for the scaled SNRs in the frame are then averaged at step 120. The frame capacity is then mapped to an effective SNR for the transmission format at step 125. A margin is added to the effective SNR at step 130. Steps 110-130 are repeated for additional transmission formats at step 135. When steps 110-130 have been repeated for all available transmission formats, a transmission format is selected based on the sum of the margin and the effective SNR at step 140. The transmission format is preferably selected that optimizes one or more of the system constraints (e.g., predefined modulation and coding schemes for a particular communication technique, data error rates, packet size, throughput, delay, nominal transit duration, bandwidth, bandwidth efficiency, etc.). The transmission format is reported (e.g., to an access network) by transmitting the same. In at least one embodiment, one or more of the steps are performed by a processor and can involve the execution of one or more sets of pre-stored instructions.

In a multi-channel embodiment of system 10 (e.g., having F channels), the SNRs of the pilot signals are determined for M time periods of a frame and for each of F channels, each pilot SNR is scaled to a scaled SNR for each transmission format and using a Q factor for each transmission format, a set of scaled SNRs is mapped to an effective SNR for each set of channels and for each transmission format, and the transmission format is selected based on the effective SNRs, a maximum number of channels, and one or more predetermined system constraint. To produce the effective SNRs, each of the scaled SNRs is mapped to a capacity, a frame capacity for each of F channels is determined by averaging M×F capacities of the scaled SNRs in the frame for each of F channels, and the frame capacities for each of the different sets of F channels are mapped to an effective SNR. A combination of channels with a transmission format is selected based on the effective SNRs, and the transmission format preferably optimizes one or more of the system constraints. The selected transmission format, including the corresponding channels, is reported to the access network.

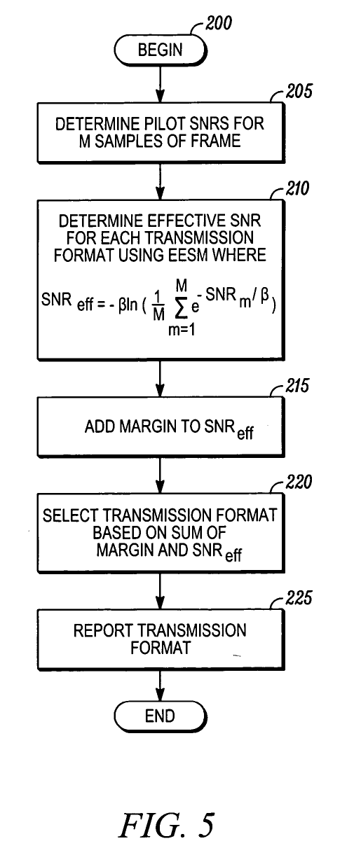

FIG. 5 is a flow diagram of another exemplary embodiment of a method 200 for mobile wireless transactions in accordance with the present invention. The method includes measuring pilot SNRs for M samples of a frame at step 205. An effective SNR is then determined for each transmission format using the Exponential Effective SNR Method at step 210. In this exemplary embodiment, the effective SNR (SNR_{eff}) is given by

$${SNR}_{eff} = - β ln ( \frac{1}{M } {\sum }_{m = 1}^{M} {ⅇ}^{- {SNR}_{m ,} / β} ) ,$$

where M is the number of pilot SNRs in the frame, and β is a predetermined optimized constant. The predetermined margin is added to the effective SNR at step 215. The transmission format that optimizes one or more of the system constraints is then determined from the value of the effective SNR and the added margin at step 220. The determined transmission format is then reported to the access network at step 225.

By having local access to all pilot SNRs, channel information, and time slot information at AT 14 and by determining the transmission format at AT 14, overhead in system 10 is reduced that would conventionally be used to transmit such information to AN 12. Additionally, converting the measured pilot SNRs to an effective SNR using ECM or the EESM reduces the amount of margin added to the effective SNR by providing a more accurate indication of data rate. In a multi-channel embodiment of system 10, an optimal combination of channels is determined using the effective SNR. Additionally, system 10 may trade some minimal increase in overhead for a greater flexibility in channel combinations. This trade-off may be particularly useful to overcome channel conflicts by transmitting information for more than a single set of channels, but less than all of the channels, and allowing the AN to make the final decision concerning any subsequent transmissions.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A method for determining a transmission format at a receiver, the method comprising:
determining a first signal-to-noise ratio (SNR) for at least one time period in a frame;
mapping the first SNRs of the frame to a second SNR for at least one transmission format to produce at least one second SNR; and
selecting the transmission format from the at least one transmission format based on the at least one second SNR.

2. A method according to claim 1, wherein said step of mapping the first SNRs comprises:
producing scaled SNRs by scaling each of the first SNRs for at least one transmission format;
mapping the scaled SNRs to capacities;
determining at least one frame capacity by averaging the capacities corresponding to the frame for each of the at least one transmission format; and
mapping each of the at least one frame capacity to a second SNR for each of at least one transmission format.

3. A method according to claim 1, wherein said step of mapping the first SNRs comprises determining the second SNR (SNR_{eff}) from the first SNRs, wherein
$${SNR}_{eff} = - β ln ( \frac{1}{M } {\sum }_{m = 1}^{M} {ⅇ}^{- {SNR}_{m} / β} )$$
where SNRₘ is the m^{th} first SNR, M is a number of first SNRs in the frame, and β is a predetermined optimized constant.

4. A method according to claim 1, wherein said step of selecting the transmission format comprises determining an expected frame error rate for each of the at least one transmission format using the at least one second SNR.

5. A method according to claim 1 further comprising adding a margin to each of the at least one second SNR prior to said step of selecting.

6. A method according to claim 1 further comprising reporting the transmission format on a control channel.

7. A method according to claim 1 further comprising adjusting the transmission format based on a rule selected from one of a table of back-off factors and a fixed margin.

8. A method according to claim 1, wherein said step of selecting comprises selecting the transmission format from the at least one transmission format based on the at least one second SNR and at least one predetermined system constraint selected from one of a throughput, a delay, a nominal transit duration, a packet size, an expected frame error rate, a bandwidth efficiency, and a bandwidth.

9. A method according to claim 1, wherein said step of mapping the first SNRs comprises mapping each first SNR to a capacity based on a modulation selected from one of a Gaussian modulation, a two-hundred and fifty-six (256) quadrature amplitude modulation (QAM), a sixty-four (64) QAM, a thirty-two (32) QAM, a sixteen (16) QAM, an eight (8) phase shift keying (PSK) modulation, and a quadrature PSK modulation, and a binary PSK modulation.

10. A method for selecting a at least one set of channels and a at least one transmission format at a receiver, the method comprising:
determining a first SNR for at least one time period in a frame and at least one channel;
producing scaled SNRs by scaling each of the first SNRs for at least one transmission format;
mapping a set of scaled SNRs to a second SNR for at least one transmission format and for at least one set of channels to produce at least one second SNR; and
selecting the at least one transmission format and the at least one corresponding set of channels based on the at least one second SNR.

11. A method according to claim 10, wherein said step of determining comprises determining a pilot SNR for each of M time periods of the frame and each of F channels in each of the at least one set of channels, and wherein said step of mapping comprises:
mapping the scaled SNRs to capacity for each of the M time periods, each of the F channels, and each of the at least one transmission format;
determining frame capacities by averaging F×M capacities of the scaled SNRs in the frame for each of the at least one transmission format; and
mapping the frame capacity to a second SNR for each of the at least one transmission format.

12. A method according to claim 10 further comprising reporting the transmission format and the at least one corresponding set of channels on a control channel.

13. A method according to claim 12, wherein said step of selecting comprises selecting the set of channels using pre-determined resource elements, each of the pre-determined resource elements defining a different set of channels.

14. A method according to claim 10 further comprising one of:
adding a margin to each of the at least one second SNR prior to said step of selecting the at least one transmission format; and
adjusting the at least one transmission format based on a rule selected from one of a table of back-off factors and a fixed margin.

15. A method according to claim 10, wherein said step of selecting comprises selecting the at least one transmission format based on the at least one second SNR, and at least one predetermined system constraint selected from a throughput, a delay, a nominal transmit duration, a packet size, an expected frame error rate, a maximum number of channels, a bandwidth efficiency, and a bandwidth.

16. A system for determining a transmission format, the system comprising:
a receiver configured to detect at least one pilot signal;
a data storage comprising:
a plurality of tables, each of said tables based on a different capacity-to-SNR mapping function; and
a plurality of scale factors, each of said scale factors based on a different transmission format; and
a processor coupled to said receiver and said data storage and comprising a set of predefined instructions to convert a set of first SNRs of different pilot signals of said at least one pilot signal to a second SNR using said plurality of tables and said plurality of scale factors and select at least one transmission format and at least one corresponding set of channels based on said second SNR.

17. A system according to claim 16 further comprising a transmitter coupled to said processor and configured to report the at least one transmission format and the at least one corresponding set of channels to an access network.

18. A system according to claim 16, wherein said set of predefined instructions comprises:
a first instruction set to determine at least one first SNR corresponding to at least one time period;
a second instruction set to produce a plurality of scaled SNRs by scaling said at least one first SNR for each of said scale factors; and
a third instruction set to convert a set of said scaled SNRs to at least one second SNR for each of said different transmission format using one of an Equivalent SNR method based on Convex Metric (ECM) and an Exponential Effective SNR Method (EESM).

19. A system according to claim 16 further comprising an access network configured to receive at least one transmission format and at least one corresponding set of channels from said transmitter and further configured to transmit to said receiver using a transmission format compatible with one of said at least one transmission format and a corresponding set of channels compatible with one of said at least one set of channels.

20. A system according to claim 16, wherein said data storage further comprises at least one of:
at least one table of back-off factors, each of said at least one table of back-off factors based on a different method for computing said second SNR; and
at least one table of margins, each of said at least one table of margins based on a different method for computing said second SNR; and
wherein said receiver is configured to use one of a back-off factor selected from said at least one table of back-off factors and a margin selected from said at least one table of margins compatible with a corresponding method for computing said second SNR.
